(19) United States
(12) Patent Application Publication
(10) Pub. No.: US 2019/0091832 A1
(43) Pub. Date: Mar. 28, 2019

(54) COMPOSITE CONDITIONER AND ASSOCIATED METHODS

(71) Applicant: Chien-Min Sung, Tansui (TW)

(72) Inventor: Chien-Min Sung, Tansui (TW)

(21) Appl. No.: 15/926,901

(22) Filed: Mar. 20, 2018

Related U.S. Application Data
(63) Continuation of application No. 15/362,464, filed on Nov. 28, 2016, now abandoned.
Application No. 15/362,464 is a continuation of application No. 13/797,704, filed on Mar. 12, 2013, now abandoned.
Application No. 13/797,704 is a continuation-in-part of application No. 12/726,786, filed on Mar. 18, 2010, now Pat. No. 8,622,787.
Application No. 12/726,786 is a continuation-in-part of application No. 12/255,823, filed on Oct. 22, 2008, now Pat. No. 8,393,934.
Application No. 12/255,823 is a continuation-in-part of application No. 12/168,110, filed on Jul. 5, 2008, now Pat. No. 8,398,466.
Application No. 12/168,110 is a continuation-in-part of application No. 11/560,817, filed on Nov. 16, 2006, now Pat. No. 7,762,872.
Application No. 11/560,817 is a continuation-in-part of application No. 11/357,713, filed on Feb. 17, 2006, now abandoned.
Application No. 13/797,704 is a continuation-in-part of application No. 12/628,859, filed on Dec. 1, 2009, now Pat. No. 7,901,272.
Application No. 12/628,859 is a continuation-in-part of application No. 11/804,221, filed on May 16, 2007, now Pat. No. 7,651,386.
Application No. 11/804,221 is a continuation of application No. 11/223,786, filed on Sep. 9, 2005, now abandoned.
Application No. 13/797,704 is a continuation-in-part of application No. 12/850,747, filed on Aug. 5, 2010, now Pat. No. 8,678,878.
Application No. 13/797,704 is a continuation-in-part of application No. 13/034,213, filed on Feb. 24, 2011, now abandoned.
(60) Provisional application No. 60/976,198, filed on Sep. 28, 2007.
(60) Provisional application No. 60/681,798, filed on May 16, 2005.
(60) Provisional application No. 61/246,816, filed on Sep. 29, 2009.
(60) Provisional application No. 61/333,162, filed on May 10, 2010.

(30) Foreign Application Priority Data
Apr. 10, 2012 (TW) 101112625

(51) Int. Cl. B24B 53/017; H01L 21/306; B24D 18/00; H01L 21/768; H01L 21/3105; H01L 21/321

(52) U.S. Cl. CPC B24B 53/017; H01L 21/30625; H01L 21/3212; H01L 21/7684; H01L 21/31055; B24D 18/0072

(57) ABSTRACT

CMP pad dressers having leveled tips and associated methods are provided. In one aspect, for example, a composite conditioner can include a base plate and a plurality of polishing units secured to a surface of the base plate by an adhesive layer, where each polishing unit includes a plurality of polishing tips secured in a binding layer. Additionally, a height difference between a first highest polishing tip and a second highest polishing tip is less than or equal to about 10 μm, a height difference between the first highest polishing tip and a tenth highest polishing tip is less than or equal to about 20 μm, and a height difference between the first highest polishing tip and a 100th highest polishing tip is less than or equal to about 40 μm. Furthermore, the first highest polishing tip protrudes from the binding layer to a height of greater than or equal to about 50 μm.

### PRIORITY DATA

This application is a continuation of U.S. patent application Ser. No. 15/362,464, filed Nov. 28, 2016, which is a continuation of U.S. patent application Ser. No. 13/797,704, filed Mar. 12, 2013, which is a continuation-in-part of U.S. patent application Ser. No. 12/726,786, filed on Mar. 18, 2010, which is a is a continuation-in-part of U.S. patent application Ser. No. 12/255,823, filed Oct. 22, 2008, which is a continuation-in-part of U.S. patent application Ser. No. 12/168,110, filed on Jul. 5, 2008, which claims the benefit of U.S. Provisional Patent Application Ser. No. 60/976,198, filed Sep. 28, 2007, and which is also a continuation-in-part of U.S. patent application Ser. No. 11/560,817, filed Nov. 16, 2006, which is a continuation-in-part of U.S. patent application Ser. No. 11/357,713, filed Feb. 17, 2006, which claims the benefit of U.S. Provisional Patent Application Ser. No. 60/681,798, filed May 16, 2005. U.S. patent application Ser. No. 13/797,704, filed Mar. 12, 2013, is additionally a continuation-in-part of U.S. patent application Ser. No. 12/628,859, filed Dec. 1, 2009, which is a continuation of U.S. patent application Ser. No. 11/804,221, filed May 16, 2007, which is a continuation of U.S. patent application Ser. No. 11/223,786, filed Sep. 9, 2005. U.S. patent application Ser. No. 13/797,704, filed Mar. 12, 2013, is also a continuation-in-part of U.S. patent application Ser. No. 12/850,747, filed Aug. 5, 2010, which claims the benefit of U.S. Provisional Patent Application Ser. No. 61/246,816, filed on Sep. 29, 2009. U.S. patent application Ser. No. 13/797,704, filed Mar. 12, 2013, is further a continuation-in-part of U.S. patent application Ser. No. 13/034,213, filed Feb. 24, 2011, which claims the benefit of U.S. Provisional Patent Application Ser. No. 61/333,162, filed on May 10, 2010. Each of these applications is incorporated herein by reference. U.S. patent application Ser. No. 13/797,704, filed Mar. 12, 2013, also claims the benefit of Taiwan Patent Application Serial No. 101112625, filed on Apr. 10, 2012, which is incorporated herein by reference.

### BACKGROUND OF THE INVENTION

For the tiny copper circuit or the interlayer tungsten circuit on the silicon wafer surface, even for the oxide film dielectric layer of the insulated circuit, making the surface flat through the planarization process to facilitate the subsequent process steps is necessary. Currently, with the process of manufacture integrated circuits (IC) on the semiconductor wafer, the most outstanding planarization technology is the chemical-mechanical planarization (CMP), which flattens a surface by pressing the wafer grinding on a rotating polishing pad.

The chemical-mechanical planarization is processed by transferring the slurry in between the wafer and the polishing pad stably and evenly to soak the polishing pad surface with slurry which containing chemicals (for instance, acid and oxidant) to erode the film on the wafer surface. The myriad of nano ceramics abrasive (ex. SiO2, Al2O3 and CeO2) in the slurry further pierce and scrape trace film, and simultaneously conduct chemical etching and mechanical grinding to remove the protruding deposit layer on the wafer. The purpose of planarization can be achieved by polishing the wafer surface.

A conditioner, whose function is to polish pad, is a necessary supply for chemical-mechanical planarization. The so-called condition is directed to shaving polishing pad surface and removing the waste accumulated on the polishing pad surface to maintain the roughness of the polishing pad surface. In addition, a conditioner could also produce tiny uplift and compression on the surface, and it is known as the height different of the asperities. Accordingly, the contact area on the polishing pad would be reduced significantly. Once the contact area becomes smaller, the contact pressure becomes greater to make the slurry at the contact point extrusion the protruding part of the wafer and the chemicals (ex. H2O2) in the slurry would be oxidation to soften or erode the wafer.

However, the waste produced in the process of the chemical-mechanical planarization, including the debris of the wafer, ex. copper wires, tungsten filled holes, oxidation film, slurry, abrasive and polishing pad scrap etc, the debris usually accumulates on the polishing pad surface and is pressed to become glaze. Once the glaze is formed, polishing pad would become slippery and difficult to maintain grinding power. Therefore, after polishing each wafer, it is necessary to utilize a conditioner to achieve the grinding efficiency of the process (ex. polishing speed) and flatness (ex. the thickness distributed of the wafer coating) as to stabilize the wafer quality.

However, previous diamond conditioner is usually secured the diamond on the metal table surface by binder. Although it is adapted for conditioning the polishing pad, with regard to the more accurate chemical-mechanical planarization process, scratch, partial dishing, erosion and thickness non-uniformity of the wafer would cause easily by the rough asperities of the polishing pad. The smaller the required IC critical dimension, the greater the demand to the flatness of the wafer surface, also the greater the demand to the conditioner, and which can lead to previous diamond conditioner not being able to satisfy the pre-requirement of the chemical-mechanical planarization process smaller than 45 nm.

In an effort to obtain a dresser with abrasive tips that are as level as possible, it is often prudent to use diamond abrasives of high shape regularity, and the crystal surface coverage of this kind of crystal is quite high, otherwise, using the crystal with low crystal surface coverage would cause an overshooting height difference. Additionally, a diamond having the highest polishing pad penetration ability, the so-called killer diamond, presents no difference when compared to other diamonds with respect to pad height. In order to meet the demand for a smaller critical dimension, continuing improvement of the conditioner is necessary. Using the sharper polishing tips and maintaining the flatness of the tips height (i.e. the difference of the polishing tips top height), making conditioner forming the subtler and more uniform nick on the polishing pad, and improving the removal ratio to the polishing pad simultaneously, by this, it is efficient to remove the hard layer and recover the asperities on the polishing pad to polish the coating on the wafer rapidly.

### SUMMARY OF THE INVENTION

The present disclosure provides efficient methods, devices, and systems of conditioning a CMP pad. In one aspect, for example, a composite conditioner can include a base plate and a plurality of polishing units secured to a surface of the base plate by an adhesive layer, where each polishing unit includes a plurality of polishing tips secured in a binding layer. Additionally, a height difference between a first highest polishing tip and a second highest polishing tip is less than or equal to about 10 μm, a height difference between the first highest polishing tip and a tenth highest polishing tip is less than or equal to about 20 μm, and a height difference between the first highest polishing tip and a 100th highest polishing tip is less than or equal to about 40 μm. Furthermore, the first highest polishing tip protrudes from the binding layer to a height of greater than or equal to about 50 μm. In some aspects, at least 1% of the plurality of polishing tips actively condition a CMP pad during a conditioning process. In other aspects, less than 40% of the surface of the base plate is covered with polishing units. The polishing units can be arranged on the plate in a variety of configurations. Non-limiting examples can include a single ring, double rings, multi-rings, radial arrangements, spiral arrangements, and the like.

In another aspect of the present disclosure, a method of making a composite conditioner can include disposing a second mold on a first mold, wherein the second mold includes a plurality of holes, placing a polishing unit in each of the plurality of holes of the second mold, where each polishing unit includes a plurality of polishing tips secured in a binding layer, applying an adhesive layer over the second mold to secure the polishing units, and removing the first mold and the second mold to form a composite conditioner. Regarding the conditioner, a height difference between a first highest polishing tip and a second highest polishing tip is less than or equal to about 10 μm, a height difference between the first highest polishing tip and a tenth highest polishing tip is less than or equal to about 20 μm, and a height difference between the first highest polishing tip and a 100th highest polishing tip is less than or equal to about 40 μm and the first highest polishing tip protrudes from the binding layer to a height of greater than or equal to about 50 μm.

In yet another aspect, a process of chemical-mechanical planarization (CMP) can include polishing a wafer against a rotating polishing pad and applying the conditioner as has been described against the polishing pad to remove debris and condition the pad.

There has thus been outlined, rather broadly, various features of the invention so that the detailed description thereof that follows may be better understood, and so that the present contribution to the art may be better appreciated. Other features of the present invention will become clearer from the following detailed description of the invention, taken with the accompanying claims, or may be learned by the practice of the invention.

### BRIEF DESCRIPTION OF THE DRAWINGS

FIG. 1A to 1G show a flow chart of manufacturing a composite conditioner in accordance with one embodiment of the present invention;

FIG. 2A to 2G show a flow chart of manufacturing the composite conditioner in accordance with one embodiment of the present invention;

FIG. 2H shows a top view of a composite CMP pad dresser in accordance with an embodiment of the present invention;

FIG. 3 shows a comparison chart of the tip height difference and the working granule amount of a conditioner in accordance with one embodiment of the present invention as compared to a prior art conditioner;

FIG. 4 shows a comparison chart of the height difference (μm) and the scratch amount of the first highest point and the second highest point of a conditioner in accordance with one embodiment of the present invention as compared to a prior art conditioner;

FIG. 5 shows a comparison chart of the scratch amount and the removal rate of a conditioner in accordance with one embodiment of the present invention as compared to a prior art conditioner;

FIG. 6 shows a comparison chart of the in use time and the removing rate of a conditioner in accordance with one embodiment of the present invention as compared to a prior art conditioner;

FIG. 7 shows a comparison chart of the polishing wafer amount and the removal rate of a conditioner in accordance with one embodiment of the present invention as compared to a prior art conditioner;

FIG. 8 shows a schematic diagram of the chemical-mechanical planarization process in accordance with one embodiment of the present invention; and

FIG. 9 shows a schematic diagram of polishing granules in accordance with one embodiment of the present invention.

It will be understood that the above figures are merely for illustrative purposes in furthering an understanding of the invention. Further, the figures are not drawn to scale, thus dimensions, particle sizes, and other aspects may, and generally are, exaggerated to make illustrations thereof clearer. Therefore, departure can be made from the specific dimensions and aspects shown in the figures in order to produce the heat spreaders of the present invention.

### DETAILED DESCRIPTION

Before the present invention is disclosed and described, it is to be understood that this invention is not limited to the particular structures, method steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

It must be noted that, as used in this specification and the appended claims, the singular forms “a,” “an” and, “the” include plural referents unless the context clearly dictates otherwise. Thus, for example, reference to “a diamond particle” includes one or more of such particles and reference to “the layer” includes reference to one or more of such layers.

### Definitions

In describing and claiming the present invention, the following terminology will be used in accordance with the definitions set forth below.

As used herein, the terms “conditioner” and “dresser” can be used interchangeably, and refer to a tool used to condition or dress a pad, such as a CMP pad.

As used herein, “dressing segment” and “polishing unit” can be used interchangeably, and refer to a dressing or conditioning element of a CMP pad dresser. Dressing segments are utilized in the present invention to carry superabrasive particles having leveled tips. Thus superabrasive particles are introduced into a CMP pad dresser by the incorporation of multiple dressing segments. It should be noted that a variety of techniques of attaching the dressing segments to the substrates, and a variety of techniques of attaching the superabrasive particles to the dressing segments, are discussed herein. It is to be understood that all of these various attachment mechanisms can be used interchangeably herein: that is, if a method of attaching a dressing segment to a substrate is discussed herein, the method of attachment discussed can also be used to attach a superabrasive particles to a dressing segment. For any particular CMP pad dresser being discussed, however, it is understood that attachment methods of the superabrasive particles to the dressing segments can differ from, or can be the same as, the method used to attach the dressing segments to the pad conditioner substrate.

As used herein, “superabrasive” may be used to refer to any crystalline, or polycrystalline material, or mixture of such materials which has a Mohr's hardness of about 8 or greater. In some aspects, the Mohr's hardness may be about 9.5 or greater. Such materials include but are not limited to diamond, polycrystalline diamond (PCD), cubic boron nitride (cBN), polycrystalline cubic boron nitride (PcBN), corundum and sapphire, as well as other superabrasive materials known to those skilled in the art. Superabrasive materials may be incorporated into the present invention in a variety of forms including particles, grits, films, layers, pieces, segments, etc. In some cases, the superabrasive materials of the present invention are in the form of polycrystalline superabrasive materials, such as PCD and PcBN materials.

As used herein, “organic material” refers to a semisolid or solid complex or mix of organic compounds. “Organic material layer” and “organic matrix” may be used interchangeably, and refer to a layer or mass of a semisolid or solid complex or mix of organic compounds, including resins, polymers, gums, etc. The organic material can be a polymer or copolymer formed from the polymerization of one or more monomers. In some cases, such organic material can be adhesive.

As used herein, the process of “brazing” is intended to refer to the creation of chemical bonds between the carbon atoms of the superabrasive particles/materials and the braze material. Further, “chemical bond” means a covalent bond, such as a carbide or boride bond, rather than mechanical or weaker inter-atom attractive forces. Thus, when “brazing” is used in connection with superabrasive particles a true chemical bond is being formed. However, when “brazing” is used in connection with metal to metal bonding the term is used in the more traditional sense of a metallurgical bond. Therefore, brazing of a superabrasive segment to a tool body does not necessarily require the presence of a carbide former.

As used herein, “particle” is as used herein in connection with diamond particles, and refers to a particulate form of diamond. Such particles may take a variety of shapes, including round, oblong, square, euhedral, etc., can be either single crystal or polycrystalline, and can have a number of mesh sizes. As is known in the art, “mesh” refers to the number of holes per unit area as in the case of U.S. meshes. All mesh sizes referred to herein are U.S. mesh unless otherwise indicated. Further, mesh sizes are generally understood to indicate an average mesh size of a given collection of particles since each particle within a particular “mesh size” may actually vary over a small distribution of sizes.

As used herein, “sharp portion” means any narrow portion to which a crystal or particle may come, including but not limited to corners, apexes, ridges, edges, obelisks, and other protrusions. In some cases, corners and/or apexes are formed at the convergence of more than two faces of the particle or crystal, or other body, disposed in intersecting planes. In other aspects, edges and/or ridges may be formed at the convergence of two or at least two faces of the particle or crystal, or other body, disposed in intersecting planes. In some aspects, “sharp portion” can include a portion that is broken, chipped, cracked, jagged, and the like. In some aspects, degrees of sharpness can be correlated with the geometric angle formed by the particle, crystal, or other body, at the location in question. In some aspects, an angle of 90 degrees or less can be considered sharp. In other aspects, an angle of 60 degrees or less can be considered sharp. In yet other aspects, and angle of 45 degrees or less, or 30 degrees or less can be considered to be sharp.

As used herein, “peripherally located,” “peripheral location” and the like, mean any particle of a dresser that is located in an area that originates at the leading edge or outer rim of a dresser and extends inwardly towards the center for up to about 90% of the radius of the dresser. In some aspects, the area may extend inwardly from about 20% to 90% of the radius. In other aspects, the area may extend in to about 50% of the radius. In yet another aspect, the area may extend in to about 33% of the radius of a dresser (i.e. 66% away from the center).

As used herein, “working superabrasive particles” are superabrasive particles that touch a CMP pad during a dressing or conditioning procedure. This touching can remove debris from the surface, it can deform the surface either elastically or plastically, or it can cut the surface to create a groove. In one specific aspect, a working superabrasive particle can cut deeper than about 10 microns into a CMP pad during a dressing procedure.

As used herein, “non-working superabrasive particles” are superabrasive particles in a CMP pad dresser that do not significantly touch the pad sufficient to remove debris from the surface, deform the surface, cut the surface to create a groove.

As used herein, “overly-aggressive superabrasive particles” are superabrasive particles in a CMP pad dresser that aggressively dress or condition a CMP pad. In one aspect, aggressive superabrasive particles are superabrasive particles that cut deeper than about 50 microns into a CMP pad during a dressing procedure. In another aspect, aggressive superabrasive particles are superabrasive particles that remove at least ⅕ of the material from the CMP pad. In yet another aspect, aggressive superabrasive particles are superabrasive particles that remove at least ½ of the material from the CMP pad.

As used herein, “indicator substrate” refers to a substrate material upon which a portion of the superabrasive particles of a CMP pad dresser can be positioned and moved to make markings indicative of working superabrasive particles.

As used herein, “marking pattern” refers to a pattern on an indicator substrate created by moving superabrasive particles thereacross. The markings can be any detectable marking known, including cuts, scratches, depressions, material deposition (e.g. pigment markers, chemical markers, fluorescent markers, radioactive markers, etc.).

As used herein, “transverse” refers to a directional orientation that is cross-wise to a reference axis. In one aspect, “transverse” can include a directional orientation that is at least at a substantial right angle to the reference axis.

As used herein, “alignment orientation direction” refers to the direction of an alignment axis of the plurality of superabrasive particles. For example, a plurality of superabrasive particles aligned in a grid formation would have at least two alignment axes; an alignment axis in the column direction and an alignment axis in the row direction oriented 90° to the column direction.

As used herein, “ablate” or “ablating” refer to a process of removing a superabrasive particle from a CMP pad dresser or reducing the projection of a superabrasive particle thus reducing the degree of contact between the superabrasive particle and the indicator substrate.

As used herein, “superabrasive segment” refers to a tool body having multiple superabrasive particles associated therewith. In some aspect, a superabrasive segment can include superabrasive polycrystalline materials as cutting elements.

As used herein, a “tool substrate” refers a portion of a pad conditioner that supports abrasive materials, and to which abrasive materials and/or superabrasive segments that carry abrasive materials may be affixed. Substrates useful in the present invention may of a variety of shapes, thicknesses, or materials that are capable of supporting abrasive materials in a manner that is sufficient to provide a pad conditioner useful for its intended purpose. Substrates may be of a solid material, a powdered material that becomes solid when processed, or a flexible material. Examples of typical substrate materials include without limitation, metals, metal alloys, ceramics, relatively hard polymers or other organic materials, glasses, and mixtures thereof. Further, the substrate may include a material that aids in attaching abrasive materials to the substrate, including, without limitation, brazing alloy material, sintering aids and the like.

As used herein, “working end” refers to an end of a particle which is oriented towards the CMP pad and during a dressing operation makes contact with the pad. Most often the working end of a particle will be distal from a substrate to which the particle is attached.

As used herein, “attitude” means the position or arrangement of a superabrasive particle in relation to a defined surface, such as a substrate to which it is attached, or a CMP pad to which it is to be applied during a work operation. For example, a superabrasive particle can have an attitude that provides a specific portion of the particle in orientation toward a CMP pad.

As used herein, “sintering” refers to the joining of two or more individual particles to form a continuous solid mass. The process of sintering involves the consolidation of particles to at least partially eliminate voids between particles.

The term “metallic” refers to both metals and metalloids. Metals include those compounds typically considered metals found within the transition metals, alkali and alkali earth metals. Examples of metals are Ag, Au, Cu, Al, and Fe. Metalloids include specifically Si, B, Ge, Sb, As, and Te. Metallic materials also include alloys or mixtures that include metallic materials. Such alloys or mixtures may further include additional additives. In the present invention, carbide formers and carbon wetting agents may be included as alloys or mixtures, but are not anticipated to be the only metallic component. Examples of such carbide formers are Sc, Y, Ti, Zr, Hf, V, Nb, Cr, Mo, Mn, Ta, W, and Tc. Examples of carbon wetting agents are Co, Ni, Mn, and Cr.

As used herein, “infiltrating” refers to a situation where a material is heated to its melting point and then flows as a liquid through the interstitial voids between particles.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained.

The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually. This same principle applies to ranges reciting only one numerical value as a minimum or a maximum. Furthermore, such an interpretation should apply regardless of the breadth of the range or the characteristics being described.

The Invention

One objective according to some aspects of the present invention is to provide a composite conditioner, which is utilizing the shape of polishing tips while maintaining the distribution of tip height to avoid the over aggressive cutting of highly exposed abrasives (e.g. killer diamond) so as to improve the ratio of working polishing tips on the polishing pad during conditioning, and to increase the removal ratio from the wafer and the durability of the conditioner.

In one embodiment, for example, a composite conditioner can include a base plate and a plurality of polishing units secured to a surface of the base plate by an adhesive layer, where each polishing unit includes a plurality of polishing tips secured in a binding layer. The height difference between the first highest polishing tip and the second highest polishing tip is less than or equal to about 10 μm, the height difference between the first highest polishing tip and the tenth highest polishing tip is less than or equal to about 20 μm, and the height difference between the first highest polishing tip and the 100th highest polishing tip is less than or equal to about 40 μm. Furthermore, the first highest polishing tip protrudes from the binding layer to a height of greater than or equal to about 50 μm.

Due to the fact the chemical-mechanical planarization (CMP) is directed to planar polishing, the contact distribution between the high point of the wafer and the polishing pad leads to confirm the quality (i.e. yield rate) and the efficiency (i.e. production capacity) of the CMP. If the distribution of the high point of the asperities in the CMP pad is uneven, the abrasion rate of the wafer in different parts of the polishing pad would be different and the wafer surface may become uneven. Furthermore, it is possible that some areas would be over-polished to result in dishing or layer erosion; or in some cases can result in under-polished regions producing residuals. If within wafer non-uniformity (WIWNU) is high, the effect of the chemical-mechanical planarization would be not desired. Accordingly, the present disclosure provides an enhanced conditioner based on extensive data from testing and experiment, and especially adjusts the height of the working polishing tips by a thickness adjustable adhesive layer to compensate for the difference of polishing units thickness and achieve aforesaid height distribution of the highest tip to avoid producing killer diamond and improve the ratio of the effective working polishing tips on the polishing units.

With regard to the present invention aforesaid composite conditioner the material of the thickness adjustable adhesive layer could be any suitable organic adhesive. Each polishing unit further comprises a unit substrate, and a binding layer is positioned between the surface of the unit substrate and the polishing tips. This binding layer can be a solder, a braze, an organic polymer, a plating layer, a sintered layer, a resin layer, or the like. The polishing tips refer to tips, a plurality of which are located on each polishing unit, can achieve the polishing effect, and the tips are exposed at the binding layer, that is, the height of the polishing tips means the height of the polishing tips protrude over the binding layer surface.

With regard to high-precision measurement for the height of the polishing tips, various techniques are contemplated. In one aspect, for example, measurement can be accomplished by an optical detection system such as the surface detector manufactured by Germany FRT (Fries Research & Technology GmbH). The surface detector detects the height of total polishing tips (ex. more than 10000) of the conditioner, that is, detects the height of the polishing tips protrusion over the binding layer surface. Using the least square method with the height data, a theorized plane may be calculated across the tops of the polishing tips. The first highest tip is the height of the polishing tip that protrudes over the theorized plane to the greatest extent, the second highest tip is the height of the polishing tip that protrudes over the theorized plane to the second most extent, and so on.

The position of the wafer to be polished mostly depends on the distribution of the polishing pad top, and the distribution depends on the height of the polishing tips of the conditioner. The conditioner can be disk-shaped (as adapted for Applied Materials) or ring-shaped (as adapted for Ebara). The diameter of the disk can be about 100 mm in general, and the diameter of the ring can be greater than 250 mm. Generally, there are tens of thousands polishing tips (e.g. diamond particles) distributed on the conditioner, for example: the polishing tips of 80/90 mesh, 100/120 mesh and 120/140 mesh, but the difference in size might be greater than 30% even in the same mesh. Additionally, there can also be a difference in size in similar polishing tips when oriented different directions; for example, the distance between the tips is 30% greater than that between particle planes, and if the shape of the polishing tips is not regular, the difference would be greater.

Therefore, the present invention regulates the polishing particles such that the height difference between the first highest polishing tip and the second highest polishing tip is less than or equal to about 10 μm, the height difference between the first highest polishing tip and the tenth highest polishing tip is less than or equal to about 20 μm, and the height difference between the first highest polishing tip and the 100th highest polishing tip is less than or equal to about 40 μm, and the first highest polishing tip protrudes from the binding layer to a height of greater than or equal to about 50 μm to ensure that there are sufficient working tips in the conditioner to achieve effective polishing of the IC wafer surface rapidly and uniformly. Additionally, it should be noted that the first highest tip and the second highest tip might be located in different polishing units or at the same polishing unit, similar with the other polishing tips; in another words, the tip distribution is not centralized at single polishing unit.

With respect to the aforesaid composite conditioner, the particles of the polishing tips can be any superabrasive material, including, without limitation, artificial or natural diamond, polycrystalline diamond (PCD), cubic boron nitride (CBN), poly crystal cubic boron nitride (PCBN), or a combination thereof. In some aspects, particle size can be in the range from about 100 μm to about 500 μm. The aforesaid diamond can be deposition diamond, polycrystalline diamond or the combination thereof. Additionally, there is no restriction to the material of the base plate, for example, resin, metal, alloy, plastic, rubber, ceramics, glass or the combination thereof (examples include the admixture between resin and alloy).

Additionally, in some cases diamond is formed by transforming graphite with iron-nickel alloy at high pressure (ex. 5 GPa), thus leaving iron-nickel inclusion inside. The alloy can transform the diamond back to the graphite or carbon at high temperature, and the volume will increase substantially to often split the diamond. Thus, diamond secured to the diamond disk by brazing can be problematic in these cases where high temperature of the braze can cause the diamond to split. In the CMP process, such fractured diamond tips may crumble along the micro-fracture surface, releasing diamond chips that can scratch the wafer. In some aspects, an electromagnetic separator can be used to separate diamond particles having excessive metal inclusions. In some aspects, it can be beneficial to choose a low melting point solder for attaching the diamond particles to the polishing units.

In the present invention, when choosing the solder as the material of the binding layer, the solder layer could comprise greater than about 1 weight percentage of at least one of Cr, B, P, Ti and alloys thereof, and greater than about 50 weight percentage of at least one of: Ni, Cu and alloys thereof. The Cr, B, P, Ti etc. can be used for activating the solder layer. Specifically, the solder can be is Ni—Cr—B, Ni—Cr—P, or Cu—Sn—Ti alloy, where the melting point is between about 800° C. and about 1000° C.

Additionally, each polishing unit can further selectively include a metal cover layer which covers on the surface of the binding layer, and the material of the metal cover layer can be at least one of Ni, Cr, Pd, Co, Pt, Au, Ti, Cu, W and alloys thereof to further adhere the polishing tips on the unit substrate of the polishing unit. Furthermore, each polishing unit further selectively comprises a protective layer which is thin inert material and covers on the surface of the metal cover layer, and the material of the protective layer is metal such as Pd, Pt, or non-metal as silicon carbide, silicon nitride, aluminum nitride, alumina, zirconia, diamond-like carbon (DLC), organic film (as Teflon) or a combination thereof to avoid the solder be eroded by the polishing slurry (ex. pH=3 tungsten process slurry).

Generally, the height of the diamond tips will determine the power pressed into the polishing pad but the sharpness will affect the depth of the diamond penetration into the polishing pad. In general, when the diamond gets sharper, the polishing pad deformation of elasticity and plasticity will be smaller, and the depth of cut is greater. Because the diamond abrasive formed on the conditioner surface is different in shape and direction, the top hundred-height diamond could contact the polishing pad. If the diamond is regular in shape and in symmetry, the angle will be obtuse and may be difficult to pierce into the polishing pad, and the diamond will push onto the polishing pad surface and form protruding plastic deformation from two sides; on the other hand, if the diamond has a sharp surface, which if not regular in shape, it may pierce into the polishing pad, cut the polishing pad surface and remove the waste simultaneously.

Therefore, with regard to the aforesaid composite conditioner of the present invention, the crystal surface coverage of more than 50% of the top 100 height polishing tips are less than 80%, and the preferred is less than 50%.

In some aspects, the highest 100 diamond tips may dress or condition less than 50% of a CMP pad. In other words, the 100 highest diamond tips perform less than 50% of the overall dressing workload. In some aspects, the workload is less than 80% of the overall dressing workload. In additional aspects, the 10 highest tips may dress or condition less than 50% of the CMP pad. Again, in this respect, the 10 highest diamond tips perform less than 50% of the overall dressing workload. In some aspects, the workload is less than 80%. Conversely described, the diamond particles in the dresser outside of the highest 100 or 10 may perform more than 50% of the overall dressing workload. In some aspects, the overall workload may be more than 80%.

As the crystal surface coverage of the polishing tips becomes lower that those polishing tips have more crack surface (sharp surface) and the polishing tips of the polishing unit working surface comprises corners and ridges, have more ridges with the angle less than 45° (means the angle of the two crystal surface which form the ridge), or have more angle less than 90°, therefore have higher removal ratio for the polishing pad.

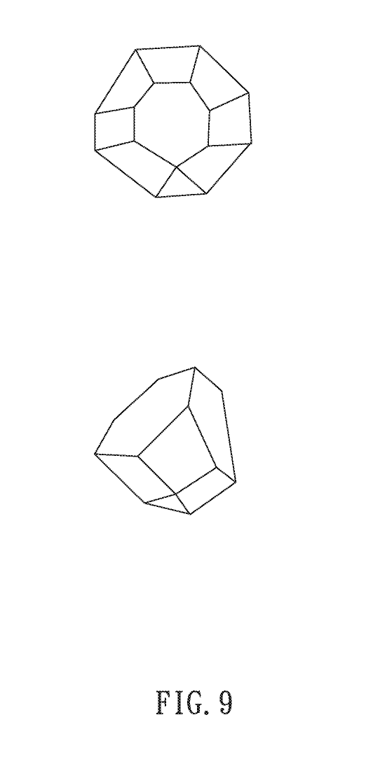

Referring now to FIG. 9, the schematic diagram to polish abrasive, wherein A, E and S respectively points to corner, ridge and surface, wherein S₁ is the crystal surface, A₁ is the angle of the crystal surface, S₂ is the crack surface and A₂ is the angle of at least one crack surface. From this, A₁ and A₂ are two different angle, A₁ is greater than 90° (obtuse angle) and A₂ is less than 90° (acute angle), means that when using A₂ as polishing tips, the removal efficiency is greater than A₁.

The polishing tips can be arranged in a pattern on the unit substrate or the polishing tips form a plurality of clusters and the clusters are arranged in a pattern on the unit substrate, where each the cluster is composed of two to six polishing tips.

Additionally, the polishing units can be arranged on the base plate as single ring, double rings, multi-rings, radial or spiral in shape and it could be disk in shape, blade in shape or polygon. If the polishing units are disk in shape, the diameter is in the range of 5 mm to 30 mm. The diameter in the range of 14 mm to 18 mm is preferred. The base plate also could be disk in shape and the diameter is in the range of 80 mm to 120 mm. It also could secure the polishing unit on the ring substrate, which is 250 mm to 270 mm in diameter, for actual use. Additionally, if the polishing unit with a disk shape is positioned at an inner surface, the polishing unit on the inner surface can be obstructed by the outer polishing units when conditioning the polishing pad, so that the inner polishing unit may not function well. Therefore, the polishing units can be arranged at the outer edge of the disk-shape base plate surface, it could create a fringe effect on a outer edge during the CMP process, such that it will increase the working amount of the polishing units, and the CMP process is adapted to apply for the nanometer process of 18 inch wafer or 22 nm wire.

In the aforesaid composite conditioner of the present invention, the spacing between the polishing units is not less than 0.1 mm, a spacing of greater than 0.5 mm is preferred, so it could be sure that in the CMP process, the slurry could flow favorably along the spacing between the polishing units and would not remain inside due to defect as the scratch to the wafer. Besides, the thickness of the binding layer of the polishing unit's bottom is in the range less than 0.6 mm so that it could fully adjust the polishing tips of each polishing unit to the same plane to increase the amount of the diamonds efficiently.

Formerly, the height difference of the tips is too big so that the amount of the tips utilized by traditional conditioner (comprising the tips piercing into polishing pad) is less than 1% of the tips total amount and the diamond coverage area of traditional conditioner is over 40%; on the other hand, in the aforesaid composite conditioner of the present invention, the amount of the polishing tips used for conditioning a polishing pad is more than 1% of the total polishing tips; besides, the area of the polishing units covering the base plate is less than 40% of the total area of the base plate surface to achieve the best remove ratio.

It is another objective of the present invention to provide a manufacture method of a composite conditioner, wherein using the polishing unit with sharp polishing tips, through the inversion method, setting the top several tips of each polishing unit as standard plane, adjusting the thickness of the binding material under each polishing unit to secure on the substrate so that the top several tips of the polishing units would not protrude to form the destructive “killer diamond”. Using coplanar to make the highest point of each polishing unit achieve common height could also improve the ratio of working polishing tips, further to improve the removal ratio and durability of the conditioner.

As such, another embodiment of the present invention provides a manufacture method of a composite conditioner, including the following steps: installing a second mold on a first mold, wherein the second mold comprises a plurality of holes; installing a polishing unit in each the hole of the second mold, wherein each the polishing unit comprises a plurality of polishing tips and a binding layer securing the polishing tips; forming a thickness adjustable adhesive layer to secure the polishing units on a base plate; and removing the first mold and the second mold to form a composite conditioner, wherein the height difference between a first and a second highest tip, between the first and a tenth highest tip, and between the first and a 100th highest tip protruding from a predetermined plane is respectively less than 10 μm, 20 μm, and 40 μm, and the height of the first highest tip protruding the binding layer is greater than 50 μm.

Generally, diamond conditioner is made by additive manufacturing method, that is, arranging in flat the diamond abrasive (like matrix distribution) on the plane substrate (as stainless steel No. 316). Obtaining a diamond conditioner or tool with diamond particles having a height difference of the diamond top of single conditioner surface of about 50 μm or less is difficult using know methods of securing the diamond abrasive such as electroplating with nickel or by brazing with an alloy, which suffers from curdling and gripping due to surface tensions when the braze is liquified. The former diamond surface is usually upward and the latter tips or the ridge usually protrude, and the diamonds with surface upward pierce into the polishing pad with difficulty and the diamond with tips or the ridge cut the polishing pad more easily. In contrast, the present invention can utilize electroplating first to form polishing units, combines organic flexible material and compensates a plurality of polishing units to arrange the polishing units at the base plate, it not only has the advantage of brazing but also could avoid the disadvantage thereof. Therefore, when the diamond conditioner is conditioning the polishing pad, the protrusion diamond top could contact and pierce into the polishing pad without having the polishing tips protruding too much, so piercing into the polishing pad too deep may increase the height difference between the asperities and therefore preventing the outstanding asperities from dipping too much slurry, and ultimately leading to the nano particle of the slurry to penetrate excessively into the wafer surface to produce over-polishing, and even scratching the wafer.

With the aforesaid manufacture method of a composite conditioner of the present invention, the thickness adjustable adhesive layer could be formed after using another plate to leveling the top tips of the polishing units, or after forming the thickness adjustable adhesive layer before the thickness adjustable adhesive layer solidified using the base plate to leveling the top tips of the polishing units.

The thickness adjustable adhesive layer could be composed by the organic adhesive, for example: a plastic material, a rubber material, a hot melt adhesive or the combination thereof; besides, the holes of the second mold are arranged at the second mold outer. Specifically, the holes of the second mold are arranged at the outer ring of the second mold as 12 holes. Additionally, with the composite conditioner, the polishing units also could be arranged at inner or outer ring, and the smaller the polishing units are, the more the amount of the working granules when polishing, but the cost of manufacturing will be higher, so manufacturing the conditioner with appropriate amount of polishing units could balance the effect and cost.

With the aforesaid manufacture method of a composite conditioner of the present invention, before the second mold set on the first mold, further comprising: forming a temporary adhesive layer on the first mold surface and setting the second mold on the temporary adhesive layer to fold the temporary adhesive layer between the second mold and the first mold, and after removing the second mold, further comprising: removing the temporary adhesive layer. With a preferred embodiment of the present invention, the temporary adhesive layer is a double-sided tape.

In another preferred embodiment of the present invention, a side of the polishing units has the polishing tips, and the thickness adjustable adhesive layer is set on the opposite side, and the polishing units set at the holes contact the first mold through the polishing tips. Besides, after removing the first mold and the second mold, further comprising: forming a mold sealing glue layer to secure the polishing units. From the above, it is possible to make the polishing units arranged orderly on the same plane by adding pressure at the side having the polishing tips of the polishing units.

With the aforesaid manufacture method of a composite conditioner of the present invention, further selectively comprising: after removing the first mold, moving the second mold. That is, the conditioner might comprise the second mold.

It is another object of the present invention to provide a chemical-mechanical planarization (CMP) process, wherein sharp polishing tips may be used while the planarity of the working surface is maintained and the ratio of the effective working polishing tips on the polishing units is improved, and the removing rate and durability are increased.

To achieve aforesaid object, another embodiment of the present invention provides a process of chemical-mechanical planarization, including the following steps: providing a polishing pad; installing a wafer on the surface of the polishing pad to polish the polishing pad with each other; and using a conditioner, which is installed on the surface of the polishing pad and removing the scrap of the polished wafer, wherein the conditioner is the aforesaid composite conditioner of the present invention.

The Moore's law states that the amount of the transistor in the same size in the same wafer will double every 18 months because of the improvement of the process technology and improved speed of the wafer executing computing. In accordance with the continuing improvement suggested by the Moore's law, the critical dimension of integrated circuit (IC) gradually exceeds the limit of 32 nm, however, the bottleneck that is occurring now is that the it is current state of art of the chemical-mechanical process is difficult to surpass, so the process could not enter a stage for finer critical dimension. In other hand, because we utilize the improved conditioner in the chemical-mechanical planarization process of the present invention, we could use the diameter of the wafer in 200 mm, 300 mm or 450 mm in the chemical-mechanical planarization process of the present invention, and the wafer surface having the IC critical dimension is smaller than or equal to 45 nm, 28 nm, or 22 nm. Therefore, if the related technology utilizes the technology of the present invention, for example applying the chemical-mechanical planarization process of the present invention for manufacturing logic device, DRAM, flash memory or hard drive, the speed of the each aforesaid device executing computing will improve as postulated by the Moore's law.

Generally speaking, because diamond sizes differ in great variety, shape and direction, and the random distance of the high point, the plough of the polishing pad and the cut manner are multifarious and which leads to uneven height of the conditioned polishing pad and then leads to difficult controlling the high point position of the wafer contacting, the area and the pressure of each contact point, and result the high variability to the polishing rate and the uniformity. When the wafer varies greatly (8 inch to 12 inch even to 18 inch in the future), the variability to the polishing rate and the uniformity will become higher, and the quality and the efficiency of the chemical-mechanical planarization process will become lower. Not only that, when the critical dimension becomes more and more narrow (45 nm to 32 nm even to 22 nm in the future), the high point of the polishing pad gets broken more easily. When the electric circuit becomes narrow, the dielectric materials therebetween have to be hollower to avoid leakage, but the hollow dielectric layer is weak, so the contact pressure of the chemical-mechanical planarization process has to weaken, but lowered contact pressure will cause the speed of polishing wafer become lower and the poor productivity.

Currently, the diamond conditioner usually adopts the method of adding diamond on the plane to manufacture, for the reason that the top height is difficult to control. Besides, under the high temperature manufacturing (as brazing), the substrates will distort to make the top height more irregular, and significantly decrease the working granule amount, and even lead to tens of thousands of diamond on the conditioner, but there are only several hundred of working granule. Because the diamond conditioner adopts addition (flattening by the top which has diamond abrasive presses thereon) to manufacture, the size, shape and direction of the diamond are difficult to control, and the diamond amount, position and piercing depth are also difficult to control, cause the predictability of the chemical-mechanical planarization process effect to greatly reduce. Although it strictly controls the flatness, diamond shape, etc. of the conditioner substrate in industry, but the improving effect is not enough.

In view that the top of the diamond is not easy to be regular, the present invention adopts a method of reversed composite, and manufactures the diamond polishing units first, and inverts the diamond polishing units on a plane to make each of the polishing tips regular. At this time, set a thickness adjustable adhesive layer at the contrary side of the polishing tips, and finally irrigate the mold sealing glue layer in (as resin) to secure all polishing units. As the aforesaid manufacturing method could avoid the “killer diamond” that is common on the diamond dish, that is, the stand up protrusion diamond. If the “killer diamond” is too sharp, it may pierce into the polishing pad too deep and pull to fracture, and then form the “killer asperities” on the polishing pad surface to cause the wafer scratch.

The following explains the implemented method of the present invention by specific concrete embodiment, and a skilled person in this art could easily understand other advantage and effect of the present invention through the content disclosed by the specification. The present invention also could be implemented and applied by other different concrete embodiment, and the detail of the present invention also could base on different view and apply for various decorations and changing without deviating the spirit of the present invention,

The drawings in the embodiment of the present invention are simplified schematic diagram. But the drawings only illustrate the components about the present invention, and the illustrated components are not the example when actually implement. The components amount, shape and ratio are s selective design when actually implement, and the components layout patterns might be more complicated.

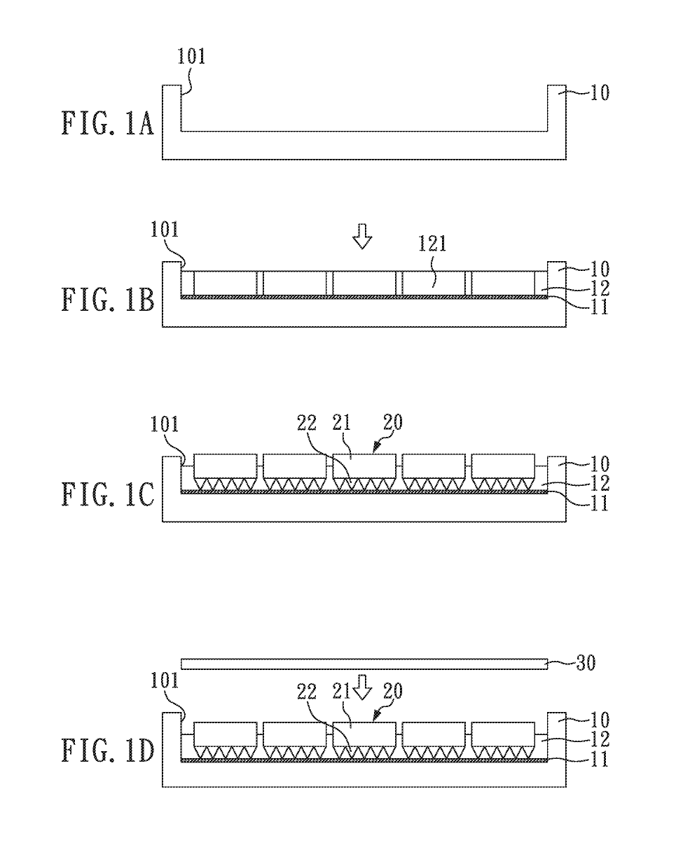

References FIG. 1A to 1G, are the flow charts of manufacturing the composite conditioner.

First of all, as shown in FIG. 1A, it provides a first mold10, and first mold10 has an opening101. Then, as FIG. 1B illustrates, it forms a temporary adhesive layer11 on opening101 surface of first mold10, and then sets a second mold12 on temporary adhesive layer11 surface to make second mold12 position in opening101 of first mold10, so temporary adhesive layer11 is between second mold12 and first mold10, wherein second mold12 has a plurality of holes121. In this preparation, temporary adhesive layer11 is a double-sided tape.

As shown in FIGS. 1C and 1G, it sets a polishing unit20 in each holes121 of second mold12, wherein each polishing unit20 comprises a plurality of polishing granules22 (each polishing granules22 at least has a polishing tip221), a unit substrate21 and a binding layer213 set between unit substrate21 surface and polishing tips221. Polishing units20 are made by general brazing, which simply explains as follow: spot-weld the solder sheet (BNi₂) at unit substrate21 with 20 mm in diameter, 4 mm in thickness, and then arrange the polishing granules (as diamond granules) on the solder sheet which is coated with viscose through the template, and then put those into the vacuum furnace exhaust to about 5 torr to 10 torr, and heating to not more than 1020° C. with 12 min last (during this the viscose is volatilized), and the solder melts to liquid and welds the diamond granules.

Because the diamond is originally positioned on a fixed solder material, when the solder melting to form as the liquid, the carbide elements (Cr) therein will diffuse to the diamond surface. So the solder will pull sink the diamonds with capillary power and climb the diamond surface to form a gradient. The diamonds will stick the solder sheet surface with plane originally, but now the rotation in the liquid will make the sharp corners up.

Then, as shown in FIGS. 1D and 1E, flatten polishing units20 by a base plate24, and fill in a thickness adjustable adhesive layer23 to secure polishing units20. Then, as shown in FIG. 1F, remove first mold10, temporary adhesive layer11 and second mold12 to form a composite conditioner2.

Composite conditioner2 comprises: a base plate24; a plurality of polishing units20 placed on a surface of base plate24, and each polishing unit20 including a plurality of polishing tips221 and a thickness adjustable adhesive layer23 which used to secure polishing units20 on the surface of base plate24, wherein, with polishing tips221, the height difference between a first and a second highest tip, between the first and a tenth highest tip, and between the first and a one hundredth highest tip protruding from a predetermined plane is respectively less than 10 μm, 20 μm, and 40 μm, and the height of the first highest tip protruding the binding layer213 is greater than 50 μm.

Referring now to FIG. 1G, it is an enlarged schematic of the polishing units of the present invention. Each polishing unit 20 comprises a plurality of polishing granules22 (each polishing granules22 at least has a polishing tip221), a unit substrate21, a binding layer213 set between unit substrate21 surface and polishing tips221, a metal cover layer212 covering on binding layer213 surface and a protective layer211 covering on metal cover layer212 surface.

Binding layer213 could be a solder layer, a plating layer, a sintering layer or a resin layer. If it is a solder layer, the solder layer comprises greater than 1 weight percentage selected at least one from the group consisting of: Cr, B, P, Ti and the alloy thereof, and greater than 50 weight percentage selected at least one from the group consisting of: Ni, Cu and the alloy thereof.

Metal cover layer212 could be formed by plating, the material of the metal cover layer is selected at least one from the group consisting of: Ni, Cr, Pd, Co, Pt, Au, Ti, Cu, W and the alloy thereof; the material of the protective layer211 is Pd, Pt, silicon carbide, aluminum nitride, alumina, zirconia, diamond-like carbon (DLC) or the combination thereof.

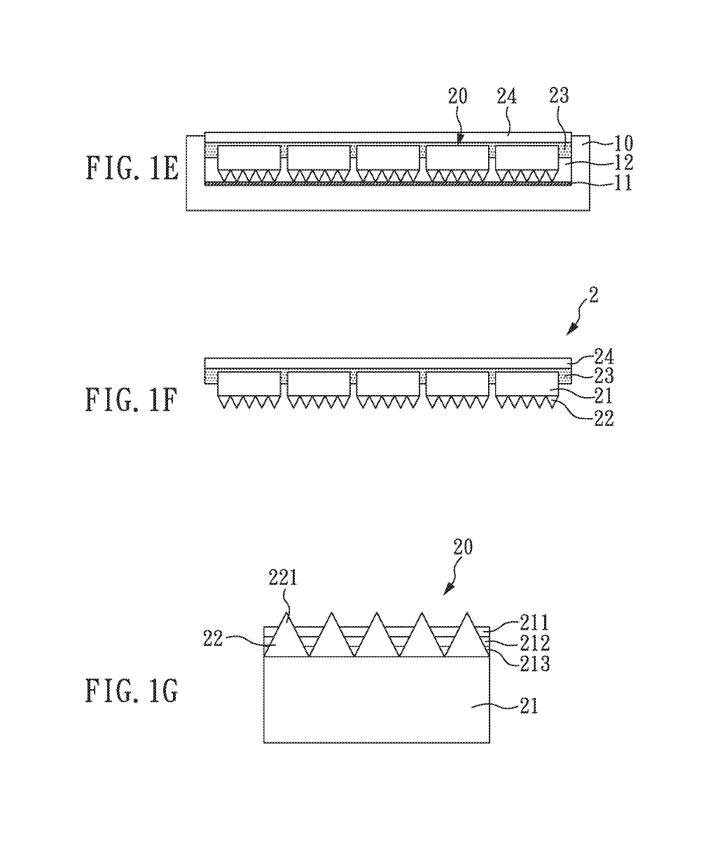

Reference to FIG. 2A to 2G, these are the flow chart of manufacturing the composite conditioner.

First of all, as shown in FIG. 2A, it provides a second mold12, and second mold12 has 12 holes121, and these holes are arranged at the outer of second mold12. Then, as shown in FIG. 2B, it set second mold12 on a first mold12 surface.

As shown in FIG. 2C, set a polishing unit20 in each holes121 of second mold12, wherein the working surface (the surface having polishing tips) of second mold12 faces to first mold12 surface. In this preparation, polishing unit20 is similar to said in preparation1. Then, as shown in FIG. 2D, it glues on the contrary side of the polishing tips of each polishing units20 to form a thickness adjustable adhesive layer23. Then, as shown in FIG. 2E, with a base plate24 presses on thickness adjustable adhesive layer23, wherein base plate24 has a notch to make base plate24 be an inverted U-shaped, and the inverted U-shaped base plate24 presses thickness adjustable adhesive layer23 by the notch.

As shown in FIG. 2F, it removes first mold10. Then, as shown in FIG. 2G, it inverts the structure of FIG. 2F, that removing second mold12, forming a mold sealing glue layer25, strengthening polishing unit20 and securing base plate24 forms a composite conditioner.

Although the polishing units made by the brazing might yield the killer diamond, but with the aforesaid method of the present invention, it could combine and use different polishing units having similar height killer diamond, and flatten the polishing tips, so the height of the killer diamond is close to that of the diamond tips on other polishing units.

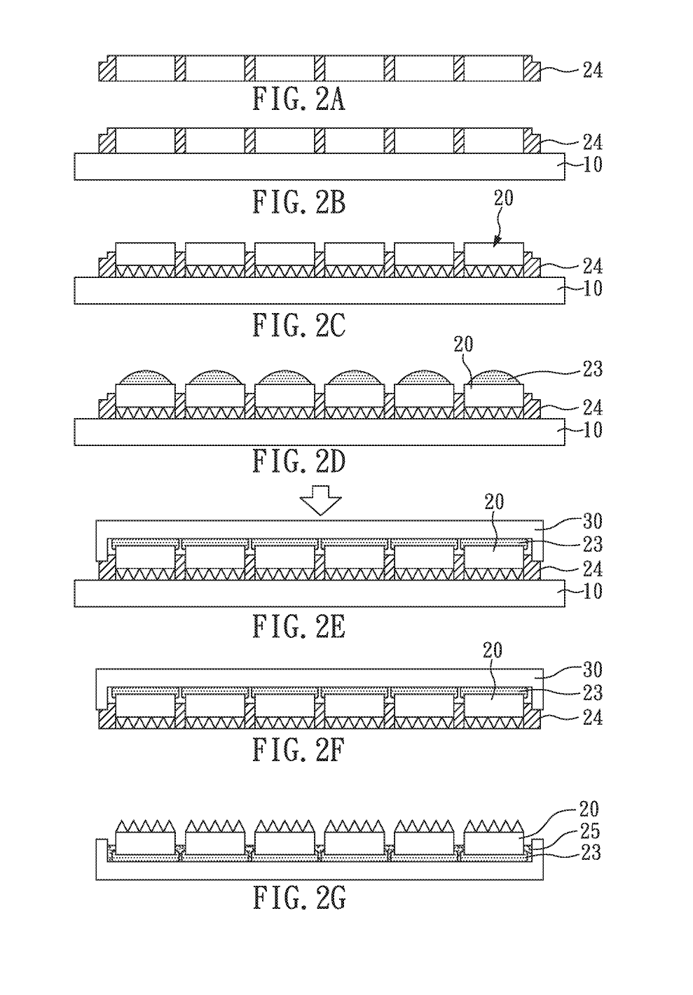

Referring now to FIG. 3, it illustrates the composite conditioner manufactured by aforesaid preparation2 (embodiment1, wherein the crystal cover ratio of the chosen diamond granules is 60% to 80%, that is PDA 878 manufactured by Element Six), the composite conditioner manufactured by conventional ceramic sintering (comparison1) and the composite conditioner manufactured by the brazing (comparison2), the comparison diagram of the tips height and working granules amount of the three conditioners. As shown in FIG. 3, when polishing, the present invention conditioner in embodiment1 has 60 to 70 working granules at the height different about 10 μm; in contrast, comparison1 and comparison2 need more tips height difference to provide more working granules amount, even the conditioner in comparison1, it needs the height difference of the polishing granules more than 40 μm to provide more than 100 working granules amount. From this, the actual working polishing granules amount for the same height difference, the present invention conditioner is far more than the prior art conditioner.

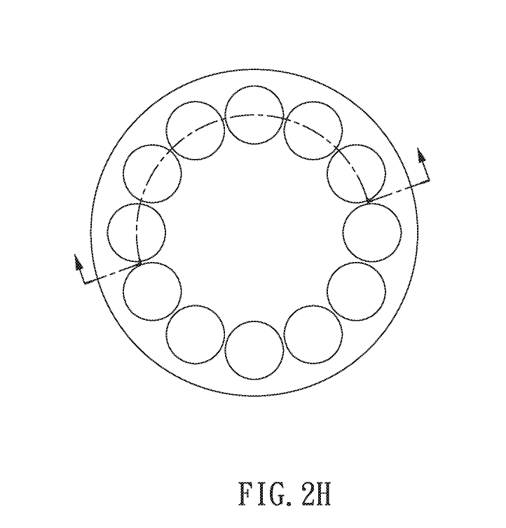

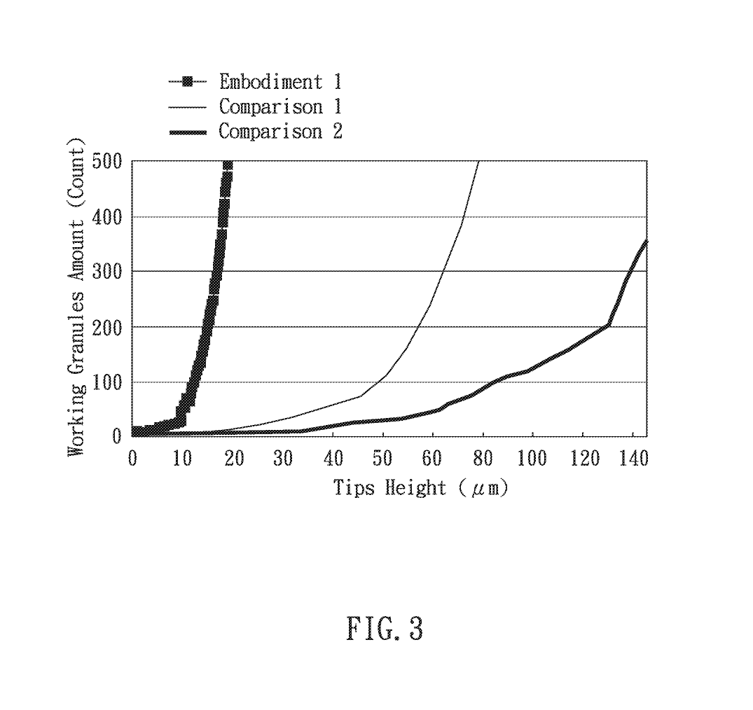

Reference to FIG. 4 and FIG. 5, it illustrates the composite conditioner manufactured by aforesaid preparation2 (embodiment1, wherein the crystal cover ratio of the chosen diamond granules is 60% to 80%, that is PDA 878 manufactured by Element Six; embodiment2, wherein the crystal cover ratio of the chosen diamond granules is 40% to 60%, that is PDA 657 manufactured by Element Six), and the composite conditioner manufactured by the brazing (comparison2), the comparison diagram of the height difference of the first high point and the second high point to the scratch amount, and the scratch amount to the removing rate of the three conditioners.

As shown in FIG. 4, with the present invention conditioner in embodiment1 and embodiment2, when the height difference of the first high point and the second high point is about 0 mm, the polishing scratch amount is between 100 to 150 scratches, that means the quality of the conditioner in embodiment1 and embodiment2 are fine, and the quality stability is nice when polishing; in contrast, with the conditioner in comparison2, the high point difference of the polishing granules is scattered mixed, and the polishing scratch amount is less than between 50 to 150 scratches, that means the quality of the conditioner in comparison2 is scattered mixed, and the quality stability is bad when polishing. On the other hand, as shown in FIG. 5, the polishing removing rate of the present invention conditioner in embodiment2 is about 250 μm to 300 μm per hour, and the scratch amount is about 100 to 150 scratches, the polishing removing rate of the present invention conditioner in embodiment1 is about 150 μm to 200 μm per hour, and the scratch amount is about 125 to 150 scratches, that means the present invention conditioner in embodiment1 and embodiment2 are high stability and is easy for quality control; in contrast, the polishing removing rate of the conditioner in comparison2 is about 125 μm to 225 μm per hour, and the scratch amount is about 50 to 75 scratches, that means the conditioner in comparison2 has low scratch amount and is unstable in quality.

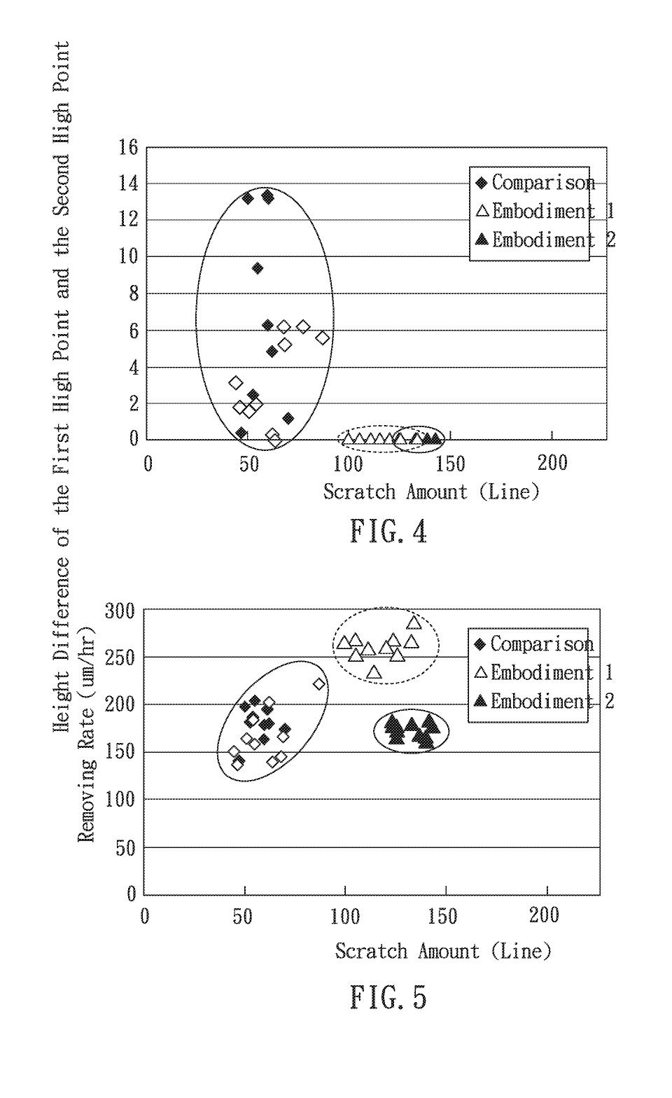

Referring next to FIG. 6, it illustrates the composite conditioner manufactured by aforesaid preparation2 (embodiment1 and embodiment2), the composite conditioner manufactured by the brazing (comparison2) and the composite conditioner manufactured by the plating (comparison3), the comparison diagram of the using time to the removing rate of the four conditioners. As shown in FIG. 6, when polishing, the removing rate of the present invention conditioner in embodiment) and embodiment2 decrease slowly with the longer using time, that means the present invention conditioner has the fastest conditioning rate and the longest durability cause of controlling the nice planeness; in contrast, the removing rate of the conditioner in comparison2 is unstable and then lead the problem in quality controlling, and the removing rate of the conditioner in comparison3 is bad, it cannot saving the polishing process time and cost.

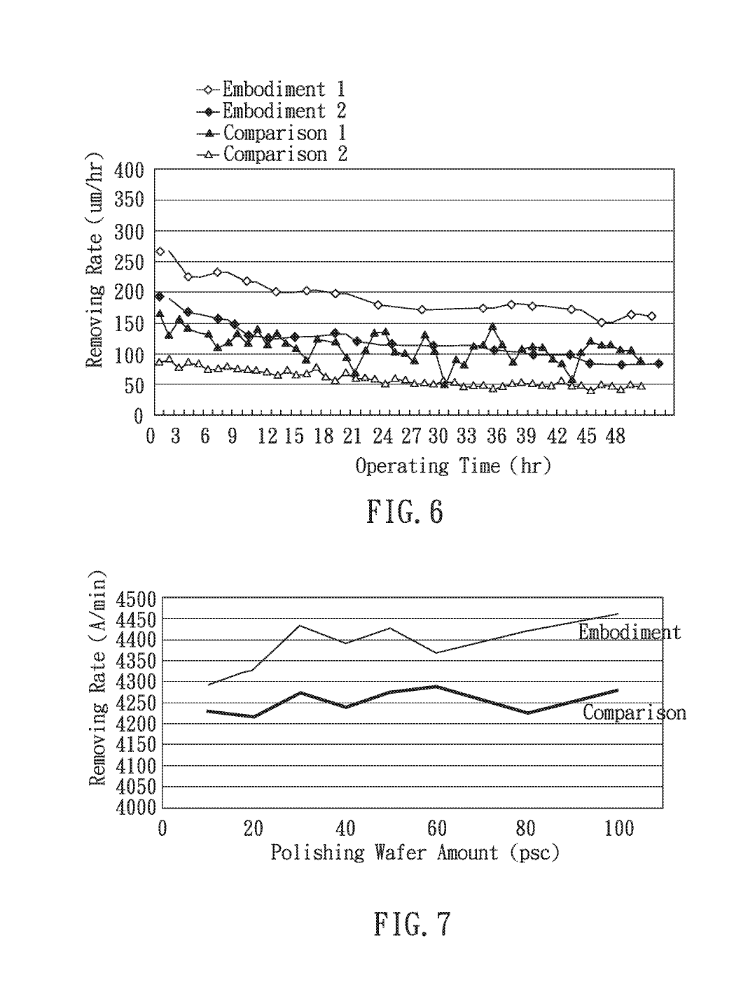

Reference to FIG. 7 illustrates the composite conditioner manufactured by aforesaid preparation2 (embodiment2), the composite conditioner manufactured by the brazing (comparison2), the comparison diagram of the polishing wafer amount to the removing rate of the two conditioners. As shown in FIG. 7, in contrast to the comparison2, the present invention conditioner in embodiment2 could use in the chemical-mechanical planarization process to achieve polishing more wafer amount.

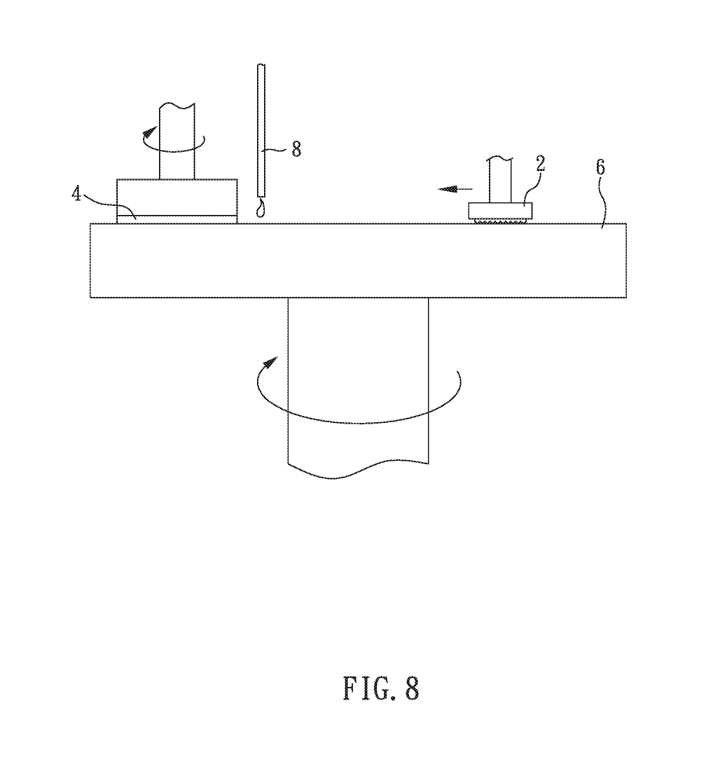

Referring to FIG. 8, it is a schematic diagram of the chemical-mechanical planarization (CMP) process. As shown in FIG. 8, generally, set a wafer4 on a polishing pad6 surface, and provide the polishing slurry by pipeline8 to polish polishing pad6 with each other, and set a conditioner2 at an another margin portion of polishing pad6 surface to remove the scrap after the wafer polished, wherein, the conditioner herein could use the conditioner manufactured by aforesaid preparation of the present invention.

From of all, recently, with convention whole piece brazing diamond conditioner, the highest polishing tip is usually higher than the second highest one in more than 20 μm, and the top 10 highest polishing granules protrusion only under 10 mm; in contrast, with the aforesaid method of the present invention, manufactured the composite conditioner by inverting uniform head method to make the difference of the highest polishing tip to the second highest one in less than 10 μm, therefore, it could improve the ratio of the effective working polishing tips on the polishing units, removing rate and durability.

Of course, it is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A composite conditioner comprising:
a base plate; and
a plurality of polishing units secured to a surface of the base plate, each polishing unit including a plurality of polishing tips secured in a binding layer, wherein a height difference between a first highest polishing tip and a second highest polishing tip is less than or equal to about 10 μm, a height difference between the first highest polishing tip and a tenth highest polishing tip is less than or equal to about 20 μm, and a height difference between the first highest polishing tip and a 100th highest polishing tip is less than or equal to about 40 μm, and the first highest polishing tip protrudes from the binding layer to a height of greater than or equal to about 50 μm.

2. The composite conditioner of claim 1, wherein at least 1% of the plurality of polishing tips actively condition a CMP pad during a conditioning process.

3. The composite conditioner of claim 1, wherein less than 40% of the surface of the base plate is covered with polishing units.

4. The composite conditioner of claim 1, wherein the polishing units are arranged on the base plate in an arrangement selected from the group consisting of a single ring, double rings, multi-rings, radial arrangements, and spiral arrangements.

5. The composite conditioner of claim 1, wherein at least one thousand polishing tips of the plurality of polishing tips condition a polishing pad during a conditioning process.

6. The composite conditioner of claim 1, wherein the plurality of polishing tips include diamond, cubic boron nitride, or a combination thereof.

7. The composite conditioner of claim 6, wherein the plurality of polishing tips include diamond, and the diamond is deposition diamond, polycrystalline diamond, or a combination thereof.

8. The composite conditioner of claim 1, wherein the crystal surface coverage of more than 50% of the top 100 height polishing tips are less than 80%.

9. The composite conditioner of claim 8, wherein the crystal surface coverage of more than 50% of the top 100 height polishing tips are less than 50%.

10. The composite conditioner of claim 1, wherein each polishing unit further includes a polishing unit substrate upon which the plurality of polishing tips are secured with the binding layer.

11. The composite conditioner of claim 1, wherein the binding layer is selected from the group consisting of a solder layer, a plating layer, a sintering layer, and a resin layer.

12. The composite conditioner of claim 11, wherein each polishing unit further comprises a metal cover layer that covers the binding layer, wherein the metal cover layer includes at least one material selected from the group consisting of Ni, Cr, Pd, Co, Pt, Au, Ti, Cu, W, and alloys thereof.

13. The composite conditioner of claim 12, wherein each polishing unit further comprises a protective layer covering the metal cover layer, wherein the protective layer includes a material selected from the group consisting of Pd, Pt, silicon carbide, aluminum nitride, alumina, zirconia, diamond-like carbon (DLC), and combinations thereof.

14. The composite conditioner of claim 11, wherein binding layer is a solder layer comprising 1 wt % or more of a first material selected from the group consisting of Cr, B, P, Ti, or an alloy thereof, or 50 wt % or more of a second material selected from the group consisting of Ni, Cu, or an alloy thereof, or 1 wt % or more of the first material and 50 wt % or more of the second material.

15. The composite conditioner of claim 1, wherein the polishing units are disc-shaped, radial-shaped, or polygon-shaped.

16. The composite conditioner of claim 15, wherein the polishing units are disc-shaped having a diameter of from about 5 mm to about 30 mm.

17. The composite conditioner of claim 1, wherein the base plate is disc-shaped having a diameter of from about 80 mm to about 120 mm.

18. The composite conditioner of claim 1, wherein the polishing tips have a particle size of from about 100 μm to about 500 μm.

19. The composite conditioner of claim 1, wherein the adhesive layer is an organic adhesive.

20. The composite conditioner of claim 1, wherein the polishing tips are arranged in a predetermined pattern on the polishing unit substrate.
